(19) United States
(12) Patent Application Publication
(10) Pub. No.: US 2026/0293141 A1
(43) Pub. Date: Sep. 24, 2026

(54) SEMICONDUCTOR DEVICE AND SEMICONDUCTOR MEMORY

(71) Applicant: Kioxia Corporation, Tokyo (JP)

(72) Inventors: Hiroyuki Kutsukake, Kuwana Mie (JP); Kazuma Yonezu, Yokkaichi Mie (JP)

(73) Assignee: Kioxia Corporation, Tokyo (JP)

(21) Appl. No.: 19/239,127

(22) Filed: Jun. 16, 2025

(30) Foreign Application Priority Data
Mar. 24, 2025 (JP) 2025-048715

(51) Int. Cl. H10B 43/40; G11C 5/06; G11C 16/04; G11C 16/14; G11C 16/26; H10B 43/10; H10B 43/27; H10B 43/35; H10D 62/10; H10D 62/60; H10D 64/66

(52) U.S. Cl. CPC H10B 43/40; G11C 5/063; G11C 16/0483; G11C 16/14; G11C 16/26; H10B 43/10; H10B 43/27; H10B 43/35; H10D 62/102; H10D 62/60; H10D 64/663

(57) ABSTRACT

A semiconductor device according to one embodiment includes first and second transistors that share one end. The semiconductor device includes a substrate, first and second insulating films, first and second conductive layers, and first, second and third contact plugs. The substrate includes first and second impurity diffusion regions. A first silicide part is formed on the second impurity diffusion region. A second silicide portion is formed on the first conductive layer except a part of the first conductive layer. A third silicide portion is formed on the second conductive layer. In plan view, the part of the first conductive layer is disposed between the first silicide part and the second silicide part.

### CROSS-REFERENCE TO RELATED APPLICATION

This application is based upon and claims the benefit of priority from Japanese Patent Application No. 2025-048715, filed Mar. 24, 2025, the entire contents of which are incorporated herein by reference.

### FIELD

Embodiments described herein relate generally to a semiconductor device and a semiconductor memory.

### BACKGROUND

A NAND flash memory capable of storing data in a nonvolatile manner is known in the art.

### BRIEF DESCRIPTION OF DRAWINGS

FIG. 1 is a block diagram showing an example of a configuration of a semiconductor memory including a semiconductor device according to a first embodiment.

FIG. 2 is a circuit diagram showing an example of a circuit configuration of a memory cell array included in the semiconductor memory according to the first embodiment.

FIG. 3 is a circuit diagram showing an example of circuit configurations of a sense amplifier module and a data register included in the semiconductor memory according to the first embodiment.

FIG. 4 is a circuit diagram showing an example of a circuit configuration of a sense amplifier unit included in the sense amplifier module provided in the semiconductor memory according to the first embodiment.

FIG. 5 is a plan view showing an example of a planar layout of the memory cell array included in the semiconductor memory according to the first embodiment.

FIG. 6 is a cross-sectional view showing an example of a cross-sectional structure of the memory cell array included in the semiconductor memory according to the first embodiment.

FIG. 7 is a plan view showing an example of a planar layout of a bit line hookup portion included in a sense amplifier unit provided in the semiconductor memory according to the first embodiment.

FIG. 8 is a cross-sectional view taken along line VIII-VIII of FIG. 7, showing an example of a cross-sectional structure of the bit line hookup portion included in the sense amplifier unit provided in the semiconductor memory according to the first embodiment.

FIG. 9 is a schematic diagram showing an example of a voltage applied to each transistor of the bit line hookup portion in an erase operation of the semiconductor memory according to the first embodiment.

FIG. 10 is a schematic diagram showing an example of a voltage applied to each transistor of the bit line hookup portion in a read operation of the semiconductor memory according to the first embodiment.

FIG. 11 is a plan view showing an example of a planar layout of a bit line hookup portion included in a sense amplifier unit provided in a semiconductor memory according to a second embodiment.

FIG. 12 is a cross-sectional view taken along line XII-XII of FIG. 11, showing an example of a cross-sectional structure of the bit line hookup portion included in the sense amplifier unit provided in the semiconductor memory according to the second embodiment.

### DETAILED DESCRIPTION

In general, according to one embodiment, a semiconductor device includes a first transistor and a second transistor that share one end. The semiconductor device includes a substrate, first and second insulating films, first and second conductive layers, and first, second and third contact plugs. The substrate includes a first impurity diffusion region and a second impurity diffusion region. The first impurity diffusion region corresponds to the one end of the first transistor and the second transistor. The second impurity diffusion region has a higher impurity concentration than the first impurity diffusion region in the first impurity diffusion region. A first silicide part is formed on the second impurity diffusion region. The first insulating film and the second insulating film are provided in a first direction on the substrate. The first insulating film corresponds to a gate insulating film of the first transistor. The second insulating film corresponds to a gate insulating film of the second transistor. The first conductive layer is provided on the first insulating film and corresponds to a gate electrode of the first transistor. A second silicide portion is formed on the first conductive layer except a part of the first conductive layer. The second conductive layer is provided on the second insulating film and corresponding to a gate electrode of the second transistor. A third silicide portion is formed on the second conductive layer. The first contact plug, a second contact plug, and a third contact plug are coupled to the first silicide part, the second silicide part, and the third silicide part, respectively. In plan view, the part of the first conductive layer is disposed between the first silicide part and the second silicide part.

Hereinafter, embodiments will be described with reference to the accompanying drawings. Each embodiment illustrates a device and a method for embodying the technical idea of the invention. The drawings are schematic or conceptual. The illustration of a configuration is omitted as appropriate. The same reference numerals are added to the components having substantially the same function and configuration. Characters, numbers, etc. added to the reference symbols are referred to by the same reference symbols and are used to distinguish between similar components.

### <1> First Embodiment

In a semiconductor device according to a first embodiment, silicide is formed in a part of a gate electrode of a transistor, thereby achieving both a decrease in contact resistance of the transistor and securing of a breakdown voltage of the transistor. Hereinafter, a three-dimensional stacked NAND flash memory (semiconductor memory) will be described as a specific example of a device using such a semiconductor device.

### <1-1> Configuration

First, a description will be given of a structure of a semiconductor memory 1 according to the first embodiment.

### <1-1-1> Overall Configuration of Semiconductor Memory 1

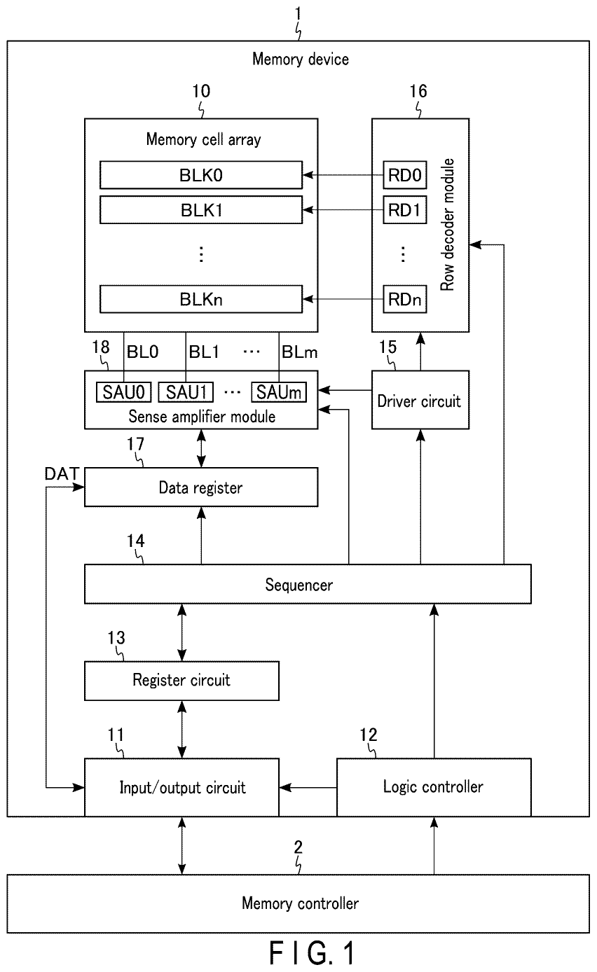

FIG. 1 is a block diagram showing an example of a configuration of the semiconductor memory 1 according to the first embodiment. As shown in FIG. 1, the semiconductor memory 1 is controlled by an external memory controller 2. The semiconductor memory 1 includes, for example, a memory cell array 10, an input/output circuit 11, a logic controller 12, a register circuit 13, a sequencer 14, a driver circuit 15, a row decoder module 16, a data register 17, and a sense amplifier module 18.

The memory cell array 10 is a set of memory cells. The memory cell array 10 includes a plurality of blocks BLK0 to BLKn (“n” is an integer equal to or larger than 1). For example, a block BLK corresponds to a data erase unit and includes a plurality of pages. A page corresponds to a unit in which data is read and written. The memory cell array 10 is provided with a plurality of bit lines BL0 to BLm (“m” is an integer equal to or larger than 1) and a plurality of word lines WL (not shown). Each memory cell is associated with a set consisting of a bit line BL and a word line WL. Where a plurality of memory cells are associated with a set consisting of the bit line BL and the word line WL, these memory cells are configured such that they can be individually accessed by select transistors.

The input/output circuit 11 is an interface circuit that controls transmission/reception (input/output) of input/output signals transmitted to/from the memory controller 2. The input/output signals include, for example, data DAT, status information, addresses, commands, and the like. The input/output circuit 11 can input/output the data DAT between the data register 17 and the memory controller 2. The input/output circuit 11 can output the status information transferred from the register circuit 13 to the memory controller 2. The input/output circuit 11 can output each of the address and the command, which are transferred from the memory controller 2, to the register circuit 13.

The logic controller 12 is a circuit that controls each of the input/output circuit 11 and the sequencer 14, based on a control signal input from the memory controller 2. The logic controller 12 commands the input/output circuit 11 to input a signal from the memory controller 2 or output a signal to the memory controller 2. In addition, the logic controller 12 notifies the input/output circuit 11 of the type (for example, any one of the data DAT, the command, and the address) of the input/output signal received by the input/output circuit 11.

The register circuit 13 is a circuit that temporarily stores a status, an address, and a command. The status is information indicating an operation state of the semiconductor memory 1. The status is updated under control of the sequencer 14 and transferred to the memory controller 2 via the input/output circuit 11. The address can include a block address, a page address, a column address, etc. The command includes a command related to various operations of the semiconductor memory 1.

The sequencer 14 is a controller that controls the overall operation of the semiconductor memory 1. The sequencer 14 executes a read operation, a write operation, an erase operation, and the like, based on the command and the address stored in the register circuit 13.

The driver circuit 15 is a circuit that generates voltages used in a read operation, a write operation, an erase operation, and the like. The driver circuit 15 supplies the generated voltages to the row decoder module 16, the sense amplifier module 18, and the like.

The row decoder module 16 is a circuit used for selecting a block BLK to be operated such as a read operation and transferring a voltage to such a wiring as a word line WL. The row decoder module 16 includes a plurality of row decoders RD0 to RDn. The row decoders RD0 to RDn are associated with the blocks BLK0 to BLKn, respectively. The detailed configuration of the row decoders RD will be described later.

The data register 17 is a circuit that temporarily stores data DAT. The data register 17 can input/output data DAT between the input/output circuit 11 and the sense amplifier module 18. The data register 17 may be referred to as a cache memory.

The sense amplifier module 18 is a circuit used for transferring a voltage to each bit line BL and for reading data. The sense amplifier module 18 includes a plurality of sense amplifier units SAU0 to SAUm. The sense amplifier units SAU0 to SAUm are associated with a plurality of bit lines BL0 to BLm, respectively. A detailed configuration of the sense amplifier unit SAU will be described later.

The combination of the semiconductor memory 1 and the memory controller 2 may constitute one semiconductor device. Examples of such a semiconductor device include a memory card such as an SD™ card, and an solid state drive (SSD).

### <1-1-2> Circuit Configuration of Semiconductor Memory 1

Hereinafter, a description will be given of the circuit configuration of the semiconductor memory 1 according to the first embodiment. In the descriptions below, a MOS transistor having a high breakdown voltage will be referred to as an “HV (High-Voltage) transistor.” A MOS transistor having a breakdown voltage lower than that of the HV transistor will be referred to as an “LV (Low-Voltage) transistor.” The LV transistor includes, for example, a gate insulating film thinner than that of the HV transistor and can operate faster than the HV transistor. In the present specification, one end of the transistor is associated with one of the source and the drain of the transistor, and the other end of the transistor is associated with the other of the source and the drain of the transistor.

### 1: Circuit Configuration of Memory Cell Array 10

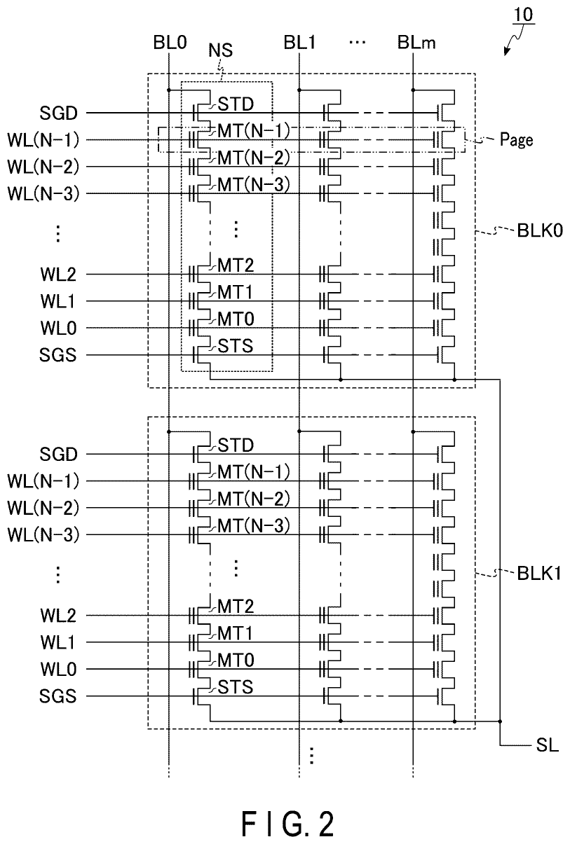

FIG. 2 is a circuit diagram showing an example of a circuit configuration of the memory cell array 10 included in the semiconductor memory 1 according to the first embodiment. FIG. 2 shows two blocks BLK0 and BLK1 among the plurality of blocks BLK included in the memory cell array 10. As shown in FIG. 2, in the memory cell array 10, the select gate lines SGD and SGS and the word lines WL0 to WL(N−1) (N is an integer equal to or larger than 2) are provided for each block BLK. The bit lines BL0 to BLm and the source line SL are shared by the plurality of blocks BLK, for example.

Each block BLK includes a plurality of NAND strings NS. The plurality of NAND strings NS are associated with the bit lines BL0 to BLm, respectively. Each NAND string NS is coupled between the associated bit line BL and the source line SL. Each NAND string NS includes, for example, N memory cell transistors MT0 to MT(N−1) and select transistors STD and STS. Each memory cell transistor MT is a memory cell having a control gate and a charge storage layer, and holds (stores) data in a nonvolatile manner. Each of the select transistors STD and STS is used to select the block BLK.

In each NAND string NS, the select transistor STD, the memory cell transistors MT(N−1) to MT0, and the select transistor STS are coupled in series in this order. Specifically, the drain and the source of the select transistor STD are coupled to the associated bit line BL and the drain of the memory cell transistor MT(N−1), respectively. The drain and the source of the select transistor STS are coupled to the source of the memory cell transistor MT0 and the source line SL, respectively. The select gate line SGD is coupled to each of the gates of a plurality of select transistors STD included in the associated block BLK. The select gate line SGS is coupled to each of the gates of a plurality of select transistors STS included in the associated block BLK. The word lines WL0 to WL(N−1) are respectively coupled to each of the control gates of the memory cell transistors MT0 to MT(N−1) included in the associated block BLK.

The “page” corresponds to a set of the memory cell transistors MT coupled to the common word line WL in the same block BLK. The set of the memory cell transistors MT coupled to the common word line WL in the same block BLK may have a storage capacity of two page data or more according to the number of bits stored in the memory cell transistors MT.

It should be noted that the circuit configuration of the memory cell array 10 may have other circuit configurations. For example, a plurality of select gate lines SGD that can be independently controlled may be provided in each block BLK. In this case, each block BLK is configured to be selectable in units of a plurality of units associated with the plurality of select gate lines SGD.

Hereinafter, a case where each NAND string NS includes ten memory cell transistors MT0 to MT9 coupled to ten word lines WL0 to WL9, respectively (that is, if N=10,) will be described as an example with respect to the semiconductor memory 1 according to the first embodiment.

### 2: Circuit Configuration of Sense Amplifier Module 18 and Data Register 17

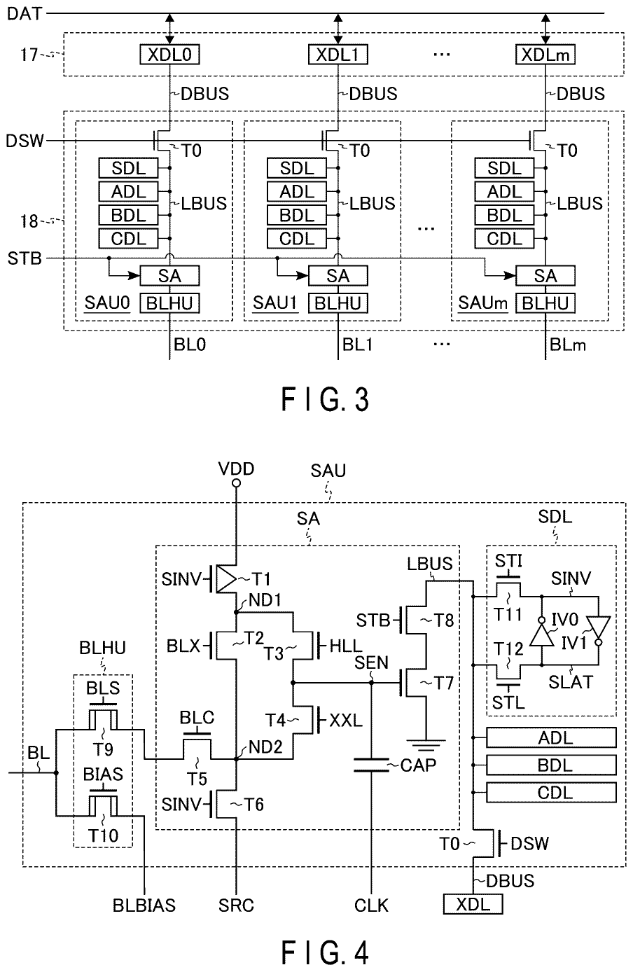

FIG. 3 is a diagram showing an example of circuit configurations of the sense amplifier module 18 and the data register 17 included in the semiconductor memory 1 according to the first embodiment. As shown in FIG. 3, each sense amplifier unit SAU includes, for example, a bit line hookup portion BLHU, a sense amplifier section SA, buses DBUS and LBUS, latch circuits SDL, ADL, BDL and CDL, and a transistor T0. The data register 17 includes, for example, a plurality of latch circuits XDL0 to XDLm. A plurality of buses DBUS of the plurality of sense amplifier units SAU0 to SAUm are coupled to the plurality of latch circuits XDL0 to XDLm, respectively.

The plurality of bit line hookup portions BLHU of the plurality of sense amplifier units SAU0 to SAUm are coupled to the plurality of bit lines BL0 to BLm, respectively. In each sense amplifier unit SAU, the sense amplifier section SA is coupled between the bus LBUS and the bit line hookup portion BLHU, and is coupled to the associated bit line BL via the bit line hookup portion BLHU. The bit line hookup portion BLHU includes, for example, a protection circuit for preventing a high voltage, which is to be applied to the channel of the NAND string NS in the erase operation, from being applied to the sense amplifier section SA.

In each sense amplifier unit SAU, the sense amplifier section SA is a circuit used for determining data, based on the voltage of the bit line BL, and for applying a voltage to the bit line BL. Where the control signal STB is asserted during the read operation, the sense amplifier section SA can determine whether the data read from the selected memory cell transistor MT is “0” data or “1” data, based on the voltage of the associated bit line BL. Control signal STB is generated, for example, by the sequencer 14.

In each sense amplifier unit SAU, each of the latch circuits SDL, ADL, BDL, and CDL can temporarily store (hold) data. The latch circuits SDL, ADL, BDL and CDL are configured such that they can transmit and receive data via the bus LBUS. The transistor T0 controls transfer of a signal between the buses DBUS and LBUS. A control signal DSW is input to the gate of the transistor T0 of each sense amplifier unit SAU. The control signal DSW is generated by the sequencer 14, for example.

Each latch circuit XDL can temporarily store (hold) data. Each latch circuit XDL is used to input/output data DAT between the sense amplifier module 18 and the input/output circuit 11. Data may be transmitted and received between the associated latch circuit XDL and the sense amplifier unit SAU via the bus DBUS. Note that one latch circuit XDL may be shared by the plurality of sense amplifier units SAU.

### 3: Circuit Configuration of Sense Amplifier Unit SAU

FIG. 4 is a circuit diagram showing an example of a circuit configuration of the sense amplifier unit SAU included in the sense amplifier module 18 provided in the semiconductor memory 1 according to the first embodiment. As shown in FIG. 4, the sense amplifier section SA includes, for example, transistors T1 to T8, a capacitor CAP, and nodes ND1, ND2, SEN and SRC. The bit line hookup portion BLHU includes, for example, the transistors T9 and T10 and the node BLBIAS. The latch circuit SDL includes, for example, inverters IV0 and IV1, transistors T11 and T12, and nodes SINV and SLAT. The transistor T1 is a p-type LV transistor. Each of the transistors T2 to T8, T11 and T12 is an n-type LV transistor. Each of the transistors T9 to T10 is an n-type HV transistor.

In the sense amplifier section SA, the source, drain, and gate of the transistor T1 are coupled to a power supply line, the node ND1, and the node SINV, respectively. The drain and source of the transistor T2 are coupled to the nodes ND1 and ND2, respectively. A control signal BLX is input to the gate of the transistor T2. The drain and source of the transistor T3 are coupled to the nodes ND1 and SEN, respectively. A control signal HLL is input to the gate of the transistor T3. The drain and source of the transistor T4 are coupled to the nodes SEN and ND2, respectively. A control signal XXL is input to the gate of the transistor T4. The drain of the transistor T5 is coupled to the node ND2. A control signal BLC is input to the gate of the transistor T5. The drain, source, and gate of the transistor T6 are coupled to the nodes ND2, SRC and SINV, respectively. The source and gate of the transistor T7 are coupled to a ground node and a node SEN, respectively. The drain of the transistor T8 is coupled to the bus LBUS. The source of the transistor T8 is coupled to the drain of the transistor T7. A control signal STB is input to the gate of the transistor T8. One electrode of the capacitor CAP is coupled to the node SEN. A clock signal CLK is input to the other electrode of the capacitor CAP.

In the bit line hookup portion BLHU, the drain of the transistor T9 is coupled to the source of the transistor T8. The source of the transistor T9 is coupled to the associated bit line BL. A control signal BLS is input to the gate of the transistor T9. The drain of the transistor T10 is coupled to the node BLBIAS. The source of the transistor T10 is coupled to the associated bit line BL. A control signal BIAS is input to the gate of the transistor T10.

The latch circuit SDL holds data at the node SLAT, and holds the inverted data at the node SINV. In the latch circuit SDL, one end and the other end of the transistor T11 are coupled to the bus LBUS and the node SINV, respectively. A control signal STI is input to the gate of the transistor T11. One end and the other end of the transistor T12 are coupled to the bus LBUS and the node SLAT, respectively. A control signal STL is input to the gate of the transistor T12. The input node and output node of the inverter IV0 are coupled to the nodes SLAT and SINV, respectively. The input node and output node of the inverter IV1 are coupled to the nodes SINV and SLAT, respectively. Each of the latch circuits ADL, BDL, and CDL has a configuration, for example, same as that of the latch circuit SDL, except that control signals supplied to a data holding node, an inverted data holding node, and the transistors T11 and T12 are prepared independently of the latch circuit SDL.

Note that, for example, the power supply voltage VDD is applied to the power supply line coupled to the transistor T1. For example, a voltage VSS is applied to the node SRC. For example, the voltage VSS is applied to the ground node coupled to the transistor T7. Each of the control signals BLX, HLL, XXL, BLC, STB, BLS, BIAS, STI and STL and the clock signal CLK is generated by the sequencer 14, for example. The number of latch circuits included in each sense amplifier unit SAU is optional. The sense amplifier unit SAU may have an arithmetic circuit capable of executing a simple logic operation.

### <1-1-3> Structure of Semiconductor Memory 1

Hereinafter, a description will be given of the structure of the semiconductor memory 1 according to the first embodiment.

In the drawings referenced below, a three-dimensional Cartesian coordinate system is used. The X direction corresponds to, for example, the direction in which the word line WL extends. The Y direction corresponds to, for example, the direction in which the bit line BL extends. The Z direction corresponds to the vertical direction with respect to the substrate of the semiconductor memory 1. The “up and down” is defined based on a direction along the Z direction. The upward direction corresponds to a direction away from the reference configuration (for example, source line SL). The downward direction corresponds to a direction approaching a reference configuration (for example, source line SL). The XZ plane (cross section) corresponds to a plane (cross section) parallel to each of the X direction and the Z direction. The YZ plane (cross section) corresponds to a plane (cross section) parallel to each of the Y direction and the Z direction. The memory cell array 10 includes a plurality of wiring layers (for example, word lines WL0 to WL9 and select gate lines SGD and SGS) stacked apart from each other in the Z direction. Hereinafter, a plurality of wiring layers (conductive layers) stacked apart from each other in the Z direction are also referred to as “stacked wiring”.

### 1: Planar Layout of Memory Cell Array 10

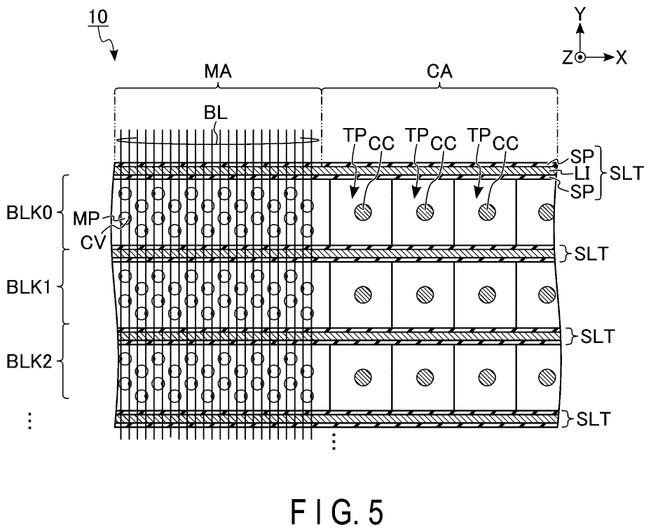

FIG. 5 is a plan view showing an example of a planar layout of the memory cell array 10 included in the semiconductor memory 1 according to the first embodiment. As shown in FIG. 5, the memory cell array 10 includes, for example, a plurality of members SLT. The memory cell array 10 includes a memory region MA and a contact region CA arranged in the X direction.

Each member SLT has a portion extending along the X direction. Each member SLT crosses the memory region MA and the contact region CA along the X direction. The plurality of members SLT are arranged in the Y direction. Each member SLT divides the stacked wiring for each block BLK. That is, in the memory cell array 10, each of the regions partitioned along the Y direction by the members SLT corresponds to one block BLK. Each member SLT includes, for example, a conductive member LI and a spacer SP. The spacer SP is an insulator provided on a side surface of the conductive member LI, and separates the conductive member LI from the stacked wiring. The conductive member LI is insulated from the stacked wiring by the spacer SP and functions as a part of the source line SL. Each member SLT may be made of an insulator.

The memory region MA is used to store data and includes a plurality of memory pillars MP and a plurality of contact plugs CV. Each memory pillar MP is, for example, a substantially cylindrical member that functions as one NAND string NS. The plurality of memory pillars MP are arranged, for example, in a lattice pattern for each block BLK. At least one bit line BL is arranged to overlap each memory pillar MP. Then, one bit line BL is electrically coupled to each memory pillar MP via a contact plug CV. Each contact plug CV includes a substantially cylindrical conductor provided extending in the Z direction. Each of the plurality of bit lines BL has a portion extending in the Y direction and is arranged in the X direction. In this example, two bit lines BL are arranged so as to overlap one memory pillar MP.

The contact region CA is used for coupling between the stacked wiring provided for each block BLK and the row decoder module 16. In the contact region CA, each wiring layer (conductive layer) included in the stacked wiring has a terrace portion TP. The terrace portion TP corresponds to the portion of the wiring layers that does not overlap the upper wiring layer. In the contact region CA, for example, a plurality of terrace portions TP corresponding to the select gate line SGD, the word lines WL9 to WL0, and the select gate line SGS are arranged in order from the memory region MA toward the end in the X direction (right side in the drawing). Note that the terrace portion TP of each wiring layer included in the stacked wiring may be provided in two or more rows of steps instead of one row of steps as described above. In addition, two terrace portions TP adjacent to each other in plan view do not necessarily need to be associated with two wiring layers adjacent to each other in the Z direction.

In addition, the contact region CA includes a plurality of contact plugs CC for each block BLK. Each contact plug CC includes a substantially cylindrical conductor provided extending in the Z direction. Each contact plug CC is electrically coupled to the terrace portion TP of any one wiring layer among the stacked wirings, and is not electrically coupled to the other wiring layers. The plurality of contact plugs CC of each block BLK are arranged in a line in the X direction in the contact region CA, for example.

In the memory cell array 10, the number and arrangement of the memory pillars MP can be designed as desired. The associated memory pillars MP and the bit lines BL may be coupled via two or more contact plugs. The number and arrangement of the contact plugs CC of each block BLK can be designed as desired. The number of contact plugs CC coupled to the terrace portion TP of each wiring layer may be one or more. The plurality of contact plugs CC of each block BLK may be arranged in a lattice pattern in the contact region CA. The memory cell array 10 may include two contact regions CA arranged so as to sandwich the memory region MA in the X direction. The contact region CA may be arranged so as to divide the memory region MA in the X direction.

### 2: Cross-Sectional Structure of Memory Cell Array 10

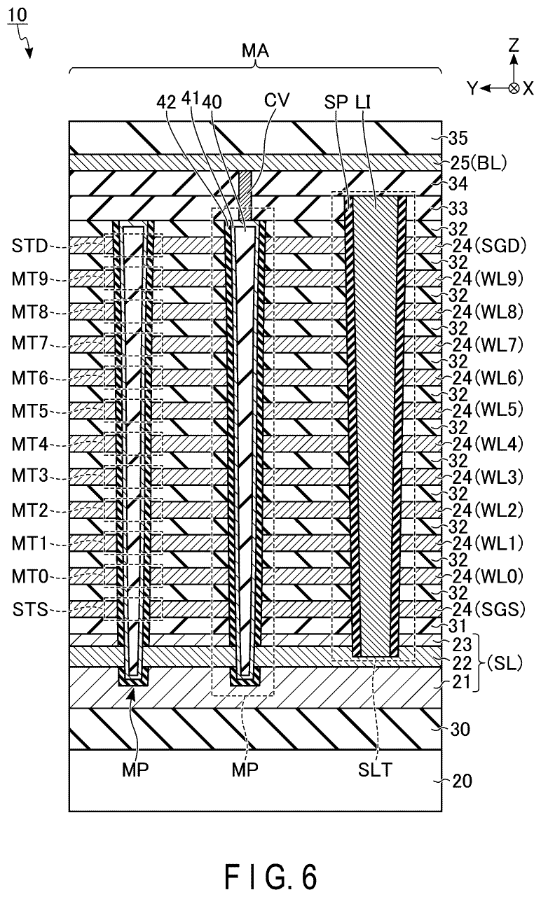

FIG. 6 is a cross-sectional view illustrating an example of a cross-sectional structure of the memory cell array 10 included in the semiconductor memory 1 according to the first embodiment. FIG. 6 shows a YZ cross section including two memory pillars MP and one member SLT in the memory region MA of the memory cell array 10. As shown in FIG. 4, the memory cell array 10 includes, for example, a substrate 20, semiconductor layers 21 to 23, conductive layers 24 and 25, and insulating layers 30 to 35.

The substrate 20 is a silicon substrate containing a p-type impurity (for example, boron or the like). The insulating layer 30 is provided on the substrate 20. The insulating layer 30 includes, for example, silicon oxide. Circuits such as the row decoder module 16 and the sense amplifier module 18 may be provided in the region where the insulating layer 30 is provided. In a case where the semiconductor memory 1 has a structure in which a chip provided with the memory cell array 10 and a chip provided with a circuit or the like other than the memory cell array 10 are bonded together, the substrate 20 provided under the insulating layer 30 may be omitted.

The semiconductor layers 21, 22, and 23 are stacked in this order on the insulating layer 30. A set of semiconductor layers 21, 22, and 23 functions as the source line SL. Each of the semiconductor layers 21, 22, and 23 contains, for example, silicon. Each of the semiconductor layers 21,22, and 23 contains, for example, phosphorus (P) as an n-type impurity.

The insulating layer 31 is provided on the semiconductor layer 23. On the insulating layer 31, for example, twelve conductive layers 24 (wiring layers) and twelve insulating layers 32 are alternately stacked one by one. The conductive layer 24 is formed, for example, as a plate spreading along the XY plane. The conductive layer 24 includes, for example, a stacked structure of titanium nitride (TiN)/tungsten (W) as a conductive material. In addition, the conductive layer 24 may contain a high dielectric constant material such as aluminum oxide. Each of the insulating layers 31 and 32 contains, for example, silicon oxide.

The insulating layer 33 is provided on the uppermost insulating layer 32. The insulating layer 34 is provided on the insulating layer 33. The conductive layer 25 is provided on the insulating layer 34. The conductive layer 25 functions as a bit line BL. The conductive layer 25 includes, for example, a portion extending in the Y direction. Although not shown, the plurality of conductive layers 25 are arranged in the X direction. The conductive layer 25 contains, for example, copper (Cu). The insulating layer 35 is provided on the conductive layer 25. Each of the insulating layers 33 to 35 contains, for example, silicon oxide.

The member SLT has a portion extending along the XZ plane, and divides the semiconductor layer 23, the insulating layer 31, the alternately stacked conductive layers 24 and insulating layers 32, and the insulating layer 33. The lower end of the member SLT reaches the semiconductor layer 22. Each of the conductive member LI and the spacer SP in the member SLT has a portion extending along the XZ plane. The conductive member LI and the plurality of conductive layers 24 are separated and insulated by the spacer SP. The lower end of the conductive member LI is electrically coupled to the semiconductor layer 22 (source line SL). The conductive member LI contains, for example, tungsten, titanium nitride, or silicon. The spacer SP contains, for example, silicon oxide.

Each memory pillar MP is provided to extend along the Z direction, and penetrates (passes) the semiconductor layer 23, the insulating layer 31, and the conductive layers 24 and the insulating layers 32 alternately stacked. A lower portion of each memory pillar MP is covered with the semiconductor layers 21, 22, and 23. Each memory pillar MP includes, for example, a core member 40, a semiconductor film 41, and a stacked film 42. The core member 40 is a substantially cylindrical insulator extending along the Z direction. The semiconductor film 41 covers the periphery of the core member 40. The semiconductor film 41 has a portion coupled to the semiconductor layer 22 (source line SL) via a part of the side surface of the memory pillar MP. The stacked film 42 covers the side surface and the bottom surface of the semiconductor film 41 except for a portion where the semiconductor film 41 and the semiconductor layer 22 are coupled. The stacked film 42 includes, for example, a tunnel insulating film, a charge storage film, and a block insulating film formed in this order from the semiconductor film 42 side. The semiconductor film 41 faces each of the plurality of conductive layers 24 arranged in the Z direction in the planar direction (for example, the Y direction) with the stacked film 42 interposed therebetween. The core member 70 contains, for example, an insulator such as silicon oxide. The semiconductor film 41 contains, for example, silicon. Each of the tunnel insulating film and the block insulating film contains silicon oxide, for example. The charge storage film functions as a charge storage layer of the memory cell transistor MT, and includes, for example, silicon nitride. The contact plug CV is coupled onto the semiconductor film 41. The contact plug CV penetrates (passes) through the insulating layers 33 and 34. The semiconductor film 41 and the conductive layer 25 are electrically coupled to each other via the contact plug CV.

In this example, the twelve conductive layers 24 are used as the select gate line SGS, the word lines WL0 to WL9, and the select gate line SGD in order from the source line SL side. A portion where the conductive layer 24 used as the select gate line SGS intersects the memory pillar MP functions as the select transistor STS. A portion where the conductive layer 24 used as the word line WL intersects the memory pillar MP functions as the memory cell transistor MT. A portion where the conductive layer 24 used as the select gate line SGD intersects the memory pillar MP functions as the select transistor STD. The semiconductor film 41 of each memory pillar MP is used as a channel (current path) of the memory cell transistors MT0 to MT9 and the select transistors STD and STS included in the NAND string NS.

### 3: Planar Layout of Bit Line Hookup Portion BLHU

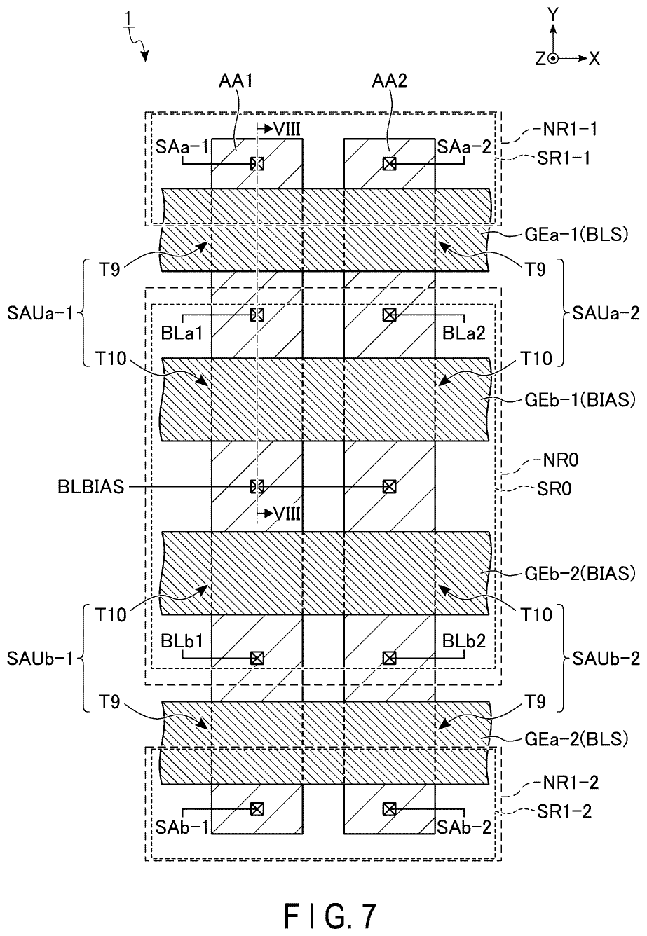

FIG. 7 is a plan view showing an example of a planar layout of the bit line hookup portion BLHU included in the sense amplifier unit SAU provided in the semiconductor memory 1 according to the first embodiment. FIG. 7 shows a case where the node BLBIAS is shared by the bit line hookup portions BLHU of four sense amplifier units SAUa-1, SAUa-2, SAUb-1, and SAUb-2. First, a configuration common to the sense amplifier units SAU will be described. As shown in FIG. 7, the semiconductor memory 1 includes, for example, an active region AA, gate electrodes GEa and GEb, silicide regions SR0 and SR1, and diffusion regions NR0 and NR1 for each bit line hookup portion BLHU.

The active region AA has a portion extending in the Y direction. Each of the gate electrodes GEa and GEb has a portion extending in the X direction. The active region AA is disposed so as to intersect each of the gate electrodes GEa and GEb. The active region AA is a region where the transistors T9 and T10 of the bit line hookup portion BLHU are formed. The gate electrode GEa is used as a gate electrode of transistor T9 of bit line hookup portion BLHU. That is, the control signal BLS is input to the gate electrode GEa. The gate electrode GEb is used as a gate electrode of transistor T10 of bit line hookup portion BLHU. That is, the control signal BIAS is input to the gate electrode GEb. Each of the diffusion regions NR0 and NR1 is a region corresponding to the source or drain of the transistor T9 or T10. Each of the silicide regions SR0 and SR1 is a region where metal silicide is formed in the diffusion regions NR0 and NR1 and the gate electrodes GEa and GEb.

The diffusion regions NR0 and NR1 are separated from each other. The silicide regions SR0 and SR1 are separated from each other. The diffusion region NR0 and the silicide region SR0 overlap each other in plan view. The width of the diffusion region NR0 in the Y direction is wider than the width of the silicide region SR0 in the Y direction. The diffusion region NR1 and the silicide region SR1 overlap each other in plan view. The width of the diffusion region NR1 in the Y direction is, for example, substantially equal to the width of the silicide region SR1 in the Y direction.

Note that the respective ranges of the diffusion regions NR0 and NR1 shown in FIG. 7 correspond to, for example, a region not covered with a mask in an ion implantation process used for forming the impurity diffusion region NP to be described later. Each range of silicide regions SR0 and SR1 shown in FIG. 7 corresponds to, for example, a region not covered with a mask in a silicide forming process described later. As the mask, a resist film formed by photolithography processing may be used, or a member (hard mask) processed into a predetermined shape may be used. The resist film used as a mask is finally removed. The member (hard mask) used as the mask may be finally removed, or a part thereof may remain.

The bit line hookup portions BLHU of the four sense amplifier units SAUa-1, SAUa-2, SAUb-1, and SAUb-2 are formed by, for example, two active regions AA1 and AA2 arranged in the X direction and four gate electrodes GEa-1, GEa-2, GEb-1, and GEb-2. The four gate electrodes GEa-1, GEb-1, GEb-2, and GEa-2 are arranged in this order in the Y direction. The gate electrodes GEa-1 and GEb-1 are shared by the sense amplifier units SAUa-1 and SAUa-2 arranged in the X direction. The gate electrodes GEa-2 and GEb-2 are shared by the sense amplifier units SAUb-1 and SAUb-2 arranged in the X direction. The diffusion region NR0 of the sense amplifier units SAUa-1 and SAUa-2 and the diffusion region NR0 of the sense amplifier units SAUb-1 and SAUb-2 are continuously provided. The silicide region SR0 of the sense amplifier units SAUa-1 and SAUa-2 and the silicide region SR0 of the sense amplifier units SAUb-1 and SAUb-2 are continuously provided. A diffusion region NR1-1 of the sense amplifier units SAUa-1 and SAUa-2 and a diffusion region NR1-2 of the sense amplifier units SAUb-1 and SAUb-2 are separated in the Y direction via the diffusion region NR0. The silicide region SR1-1 of the sense amplifier units SAUa-1 and SAUa-2 and the silicide region SR1-2 of the sense amplifier units SAUb-1 and SAUb-2 are separated in the Y direction via the silicide region SR0.

A contact plug electrically coupled to a sense amplifier section SAa-1 of the sense amplifier unit SAUa-1 is coupled to a region where the active region AA1 and the silicide region SR1-1 overlap with each other. A contact plug electrically coupled to a sense amplifier section SAa-2 of the sense amplifier unit SAUa-2 is coupled to a region where the active region AA2 and the silicide region SR1-1 overlap with each other. A contact plug electrically coupled to a sense amplifier section SAb-1 of the sense amplifier unit SAUb-1 is coupled to a region where the active region AA1 and the silicide region SR1-2 overlap with each other. A contact plug electrically coupled to a sense amplifier section SAb-2 of the sense amplifier unit SAUb-2 is coupled to a region where the active region AA2 and the silicide region SR1-2 overlap with each other.

A contact plug electrically coupled to a bit line BLa1 associated with the sense amplifier unit SAUa-1 is coupled to a region in the active region AA1 and between the gate electrodes GEa-1 and GEb-1. A contact plug electrically coupled to a bit line BLa2 associated with the sense amplifier unit SAUa-2 is coupled to a region in the active region AA2 and between the gate electrodes GEa-1 and GEb-1. A contact plug electrically coupled to a bit line BLb1 associated with the sense amplifier unit SAUb-1 is coupled to a region in the active region AA1 and between the gate electrodes GEa-2 and GEb-2. A contact plug electrically coupled to the bit line BLb2 associated with the sense amplifier unit SAUb-2 is coupled to a region in the active region AA2 and between the gate electrodes GEa-2 and GEb-2. A contact plug shared by the sense amplifier units SAUa-1 and SAUb-1 and electrically coupled to the node BLBIAS is coupled to a region in the active region AA1 and between the gate electrodes GEb-1 and GEb-2. A contact plug shared by the sense amplifier units SAUa-2 and SAUb-2 and electrically coupled to the node BLBIAS is coupled to a region in the active region AA2 and between the gate electrodes GEb-1 and GEb-2.

### 4: Cross-Sectional Structure of Bit Line Hookup Portion BLHU

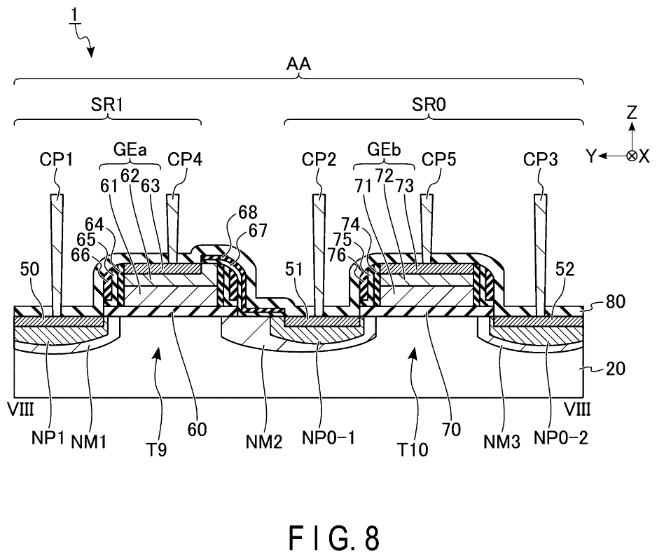

FIG. 8 is a cross-sectional view taken along line VIII-VIII of FIG. 7, showing an example of a cross-sectional structure of the bit line hookup portion BLHU included in the sense amplifier unit SAU provided in the semiconductor memory 1 according to the first embodiment. FIG. 8 shows a YZ cross section of a region including the transistors T9 and T10 included in the bit line hookup portion BLHU of one sense amplifier unit SAU. As shown in FIG. 8, the semiconductor memory 1 includes, for example, impurity diffusion regions NM1, NM2, NM3, NP1, NP0-1, and NP0-2, silicide parts 50, 51, 52, 63, and 73, gate insulating films 60 and 70, conductive layers 61, 62, 71, and 72, insulating films 64, 65, 66, 74, 75, 76, and 80, and contact plugs CP1 to CP5.

Each of the impurity diffusion regions NM1 to NM3 is a diffusion region of an n-type impurity (for example, phosphorus or the like) provided in the vicinity of the upper surface of the substrate 20. The impurity diffusion region NM1 is provided corresponding to the drain of the transistor T9. The impurity diffusion region NM2 is provided corresponding to the source of each of the transistors T9 and T10. The impurity diffusion region NM3 is provided corresponding to the drain of the transistor T10.

Each of the impurity diffusion regions NP1, NP0-1, and NP0-2 is a diffusion region of an n-type impurity (for example, phosphorus or the like) provided in the vicinity of the upper surface of the substrate 20. The n-type impurity concentration of each of the impurity diffusion regions NP0-1, NP0-2, and NP1 is higher than that of each of the impurity diffusion regions NM1 to NM3. The impurity diffusion region NP1 is provided corresponding to the drain of the transistor T9 and is provided in the impurity diffusion region NM1. The impurity diffusion region NP1 is associated with the diffusion region NR1 shown in FIG. 7. The impurity diffusion region NP0-1 is provided corresponding to the source of each of the transistors T9 and T10, and is provided in the impurity diffusion region NM2. The impurity diffusion region NP0-1 is disposed closer to the transistor T10 in the impurity diffusion region NM2. Specifically, an interval between one ends of the impurity diffusion regions NM2 and NP0-1 on one side in the X direction is wider than an interval between the other ends of the impurity diffusion regions NM2 and NP0-1 on the other side in the X direction. The impurity diffusion region NP0-2 is provided corresponding to the drain of the transistor T10 and is provided in the impurity diffusion region NM3. Each of the impurity diffusion regions NP0-1 and NP0-2 is associated with the diffusion region NR0 shown in FIG. 7.

Each of the silicide parts 50, 51, and 52 contains a metal silicide provided in the vicinity of the upper surface of the substrate 20. The silicide part 50 is provided corresponding to the drain of the transistor T9 and is formed by silicidation of a part of the impurity diffusion region NP1. The silicide part 50 is separated from a boundary portion between the impurity diffusion regions NM1 and NP1. The silicide part 51 is provided corresponding to the source of each of the transistors T9 and T10, and is formed by silicidation of a part of the impurity diffusion region NP0-1. The silicide part 51 is separated from a boundary portion between the impurity diffusion regions NM2 and NP0-1. The silicide part 52 is provided corresponding to the drain of the transistor T10 and is formed by silicidation of a part of the impurity diffusion region NP0-2. The silicide part 52 is separated from a boundary portion between the impurity diffusion regions NM3 and NP0-2. The contact plugs CP1, CP2, and CP3 are coupled to the silicide parts 50, 51, and 52, respectively. That is, the contact plug CP1 is coupled to the drain of the transistor T9. The contact plug CP2 is coupled to the respective sources of the transistors T9 and T10. The contact plug CP3 is coupled to the drain of the transistor T10.

The gate insulating film 60 is provided on the substrate 20 and is disposed between the silicide parts 50 and 51 in plan view. In plan view, one end of the gate insulating film 60 in the X direction overlaps a part of the impurity diffusion region NP1 in the Z direction, and substantially coincides with an end of the silicide part 50 in the X direction. The other end of the gate insulating film 60 in the X direction overlaps a part of the impurity diffusion region NM2 in the Z direction and is separated from the impurity diffusion region NP0-1. The gate insulating film 60 is used as a gate insulating film of the transistor T9.

A set of the conductive layers 61 and 62 and the insulating films 64, 65, and 66 is provided on the gate insulating film 60. Specifically, the conductive layer 61 is provided on the gate insulating film 60. The conductive layer 62 is provided on the conductive layer 61. The set of insulating films 64, 65, and 66 is provided on side surfaces of the conductive layers 61 and 62. The insulating films 64, 65, and 66 are formed in this order from the conductive layers 61 and 62 side. The insulating film 65 may have a portion provided between the insulating film 66 and the gate insulating film 60. Note that the conductive layers 61 and 62 may be provided integrally.

The silicide part 63 is formed by silicidation of a part of the conductive layer 62 and contains metal silicide. The silicide part 63 is provided on the conductive layer 62. The upper portion of the conductive layer 62 may have a portion that is not silicided on the transistor T10 side. Specifically, one end of the silicide part 63 in the X direction is in contact with the insulating film 64. The other end of the silicide part 63 in the X direction is separated from the insulating film 64 and is in contact with the conductive layer 62. A set of the conductive layers 61 and 62 and the silicide part 63 is used as the gate electrode GEa of the transistor T9. The contact plug CP4 is coupled to the silicide part 63. That is, the contact plug CP4 is coupled to the gate electrode GEa of the transistor T9.

A set of insulating films 67 and 68 includes a portion provided so as to cover a part of the set of the gate insulating film 60, the conductive layers 61 and 62, and the insulating films 64, 65, and 66, and a portion provided so as to cover a part of the substrate 20. Specifically, the insulating films 67 and 68 are continuously provided along an upper surface of a portion of the conductive layer 62 that is not silicided, the set of the insulating films 64 to 66, and an upper surface of the impurity diffusion region NM2 excluding the silicide part 51. The insulating films 67 and 68 are formed in this order. In the set of insulating films 67 and 68, a portion covering a part of the substrate 20 overlaps a part of the impurity diffusion regions NM2 and NP0-1 in the Z direction. Furthermore, in plan view, the position of one end of the insulating films 67 and 68 in the X direction substantially coincides with the position of the other end of the silicide part 63 in the X direction. In plan view, the positions of the other ends of the insulating films 67 and 68 in the X direction substantially coincide with the position of one end of the silicide part 51 in the X direction. The insulating film 67 contains, for example, silicon oxide. The insulating film 68 contains, for example, silicon nitride. In the portion covered with the insulating films 67 and 68, silicidation is suppressed.

The gate insulating film 70 is provided on the substrate 20 and is disposed between the silicide parts 51 and 52 in plan view. The gate insulating films 60 and 70 are arranged in the Y direction. In plan view, one end of the gate insulating film 70 in the X direction overlaps a part of the impurity diffusion region NP0-1, and substantially coincides with the other end of the silicide part 51 in the X direction. In plan view, the other end of the gate insulating film 70 in the X direction overlaps a part of the impurity diffusion region NP0-2, and substantially coincides with one end of the silicide part 52 in the X direction. The gate insulating film 70 is used as a gate insulating film of the transistor T10.

A set of the conductive layers 71 and 72 and the insulating films 74, 75, and 76 is provided on the gate insulating film 70. Specifically, the conductive layer 71 is provided on the gate insulating film 70. The conductive layer 72 is provided on the conductive layer 71. A set of insulating films 74,75, and 76 is provided on side surfaces of the conductive layers 71 and 72. The insulating films 74, 75, and 76 are formed in this order from the conductive layers 71 and 72 side. The insulating film 75 may have a portion provided between the insulating film 76 and the gate insulating film 70. Note that the conductive layers 71 and 72 may be provided integrally.

The silicide part 73 is formed by silicidation of a part of the conductive layer 72 and contains metal silicide. The silicide part 73 is provided on the conductive layer 72. The entire upper portion of the conductive layer 72 is silicided. Specifically, one end and the other end of the silicide part 73 in the X direction are in contact with the insulating film 74. A set of the conductive layers 71 and 72 and the silicide part 73 is used as the gate electrode GEb of the transistor T10. The contact plug CP5 is coupled to the silicide part 73. That is, the contact plug CP5 is coupled to the gate electrode GEb of the transistor T10.

The set of the gate insulating film 60, the conductive layers 61 and 62, the silicide part 63, and the insulating films 64 to 68 described above is a structure associated with the transistor T9. A set of the gate insulating film 70, the conductive layers 71 and 72, the silicide part 73, and the insulating films 74 to 76 is a structure associated with the transistor T10. The insulating film 80 is provided so as to cover the structure associated with the transistor T9, the structure associated with the transistor T10, and the upper surface of the substrate 20. The insulating film 80 has a portion penetrated (passed) by the plurality of contact plugs CP1 to CP5. The insulating film 80 contains, for example, silicon nitride.

In the manufacturing process of the semiconductor memory 1 described above, the impurity diffusion regions NP1, NP0-1, and NP0-2 are collectively formed. The impurity diffusion regions NM1, NM2, and NM3 are collectively formed. The gate insulating films 60 and 70 are collectively formed and contain, for example, silicon oxide. The conductive layers 61 and 71 are collectively formed and contain, for example, polysilicon. The conductive layers 62 and 72 are collectively formed and contain, for example, polysilicon. The silicide parts 50, 51, 52, 63, and 73 are collectively formed and contain, for example, at least one of nickel (Ni) and platinum (Pt). The insulating films 64 and 74 are collectively formed and contain, for example, silicon oxide. The insulating films 65 and 75 are collectively formed and contain, for example, silicon oxide. The insulating films 66 and 76 are collectively formed and contain, for example, silicon nitride.

The silicide parts 51, 52, and 73 are included in the silicide region SR0. The silicide parts 50 and 63 are included in the silicide region SR1. In each of the conductive layer 62 and the impurity diffusion region NP0-1, silicidation is suppressed in a portion covered with the insulating films 67 and 68. That is, the substrate 20 has a portion not containing silicide on the gate insulating film 60 side between the substrate and the gate insulating films 60 and 70 in plan view. Therefore, in plan view, the interval between the silicide part 51 and the silicide part 63 in the Y direction is wider than the interval between the silicide part 51 and the silicide part 73 in the Y direction. The impurity diffusion region NM2 has a portion facing each of the gate insulating films 60 and 70 in the Z direction. In plan view, an interval between the conductive layer 62 and the impurity diffusion region NP0-1 in the Y direction is wider than an interval between the conductive layer 72 and the impurity diffusion region NP0-1 in the Y direction.

### <1-2> Operation

Next, as an operation of the semiconductor memory 1 according to the first embodiment, an example of voltages applied to the transistors T9 and T10 of the bit line hookup portion BLHU will be described. Note that, in the following description, the voltage applied to the contact plug CP1 is generated by the sense amplifier section SA under the control of the sequencer 14, for example. The voltage applied to each of the contact plugs CP3 to CP5 is generated by the driver circuit 15 under the control of the sequencer 14, for example.

### <1-1-1> Erase Operation

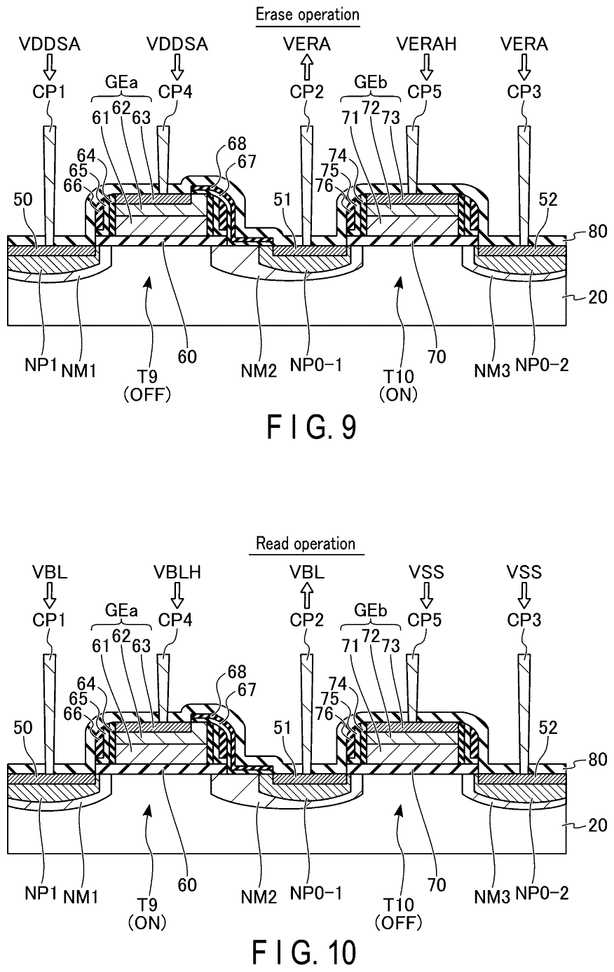

FIG. 9 is a schematic diagram illustrating an example of voltages applied to the transistors T9 and T10 of the bit line hookup portion BLHU in the erase operation of the semiconductor memory 1 according to the first embodiment. As shown in FIG. 9, in the erase operation, the voltage VDDSA is applied to the contact plug CP1 (the drain of the transistor T9), the voltage VERA is applied to the contact plug CP3 (the drain of the transistor T10), the voltage VDDSA is applied to the contact plug CP4 (the gate electrode GEa of the transistor T9), and the voltage VERAH is applied to the contact plug CP5 (the gate electrode GEb of the transistor T10).

The voltage VDDSA is a voltage that can be generated by the sense amplifier section SA, and is, for example, 2.2 V. The voltage VERA is a high voltage capable of erasing data stored in the memory cell transistor MT, and is, for example, 23 V. The voltage VERAH is higher than the voltage VERA, and is, for example, 28 V. The transistor T9 in which the voltage VDDSA is applied to each of the gate electrode GEa and the drain is turned off (OFF). The transistor T10 in which the voltages VERAH and VERA are applied to the gate electrode GEb and the drain is turned on (ON).

The transistor T10 in the ON state transfers the voltage VERA applied to the drain to the source. Then, the voltage of the bit line BL increases based on the voltage VERA applied via the silicide part 51 and the contact plug CP2. In a case where the voltage of the bit line BL increases, the channel potential of the NAND string NS rises. In this way, in a case where the channel potential of the NAND string NS is increased and the voltage of each word line WL is controlled to, for example, 0 V, the data stored in each of the plurality of memory cell transistors MT included in the NAND string NS is erased.

In the semiconductor memory 1 according to the first embodiment, the impurity diffusion region NP0-1 is arranged close to the transistor T10 on the high potential side in the impurity diffusion region NM2 shared between the transistors T9 and T10. That is, an interval between the impurity diffusion region NP0-1 and the transistor T9 is wide. The silicide part 51 is included in the impurity diffusion region NP0-1. As a result, in the semiconductor memory 1 according to the first embodiment, even if the voltage VERA is transferred to the impurity diffusion region NM2 via the transistor T10 in the erase operation, the breakdown voltage between the transistors T9 and T10 can be secured.

### <1-1-2> Read Operation

FIG. 10 is a schematic diagram illustrating an example of voltages applied to the transistors T9 and T10 of the bit line hookup portion BLHU in the read operation of the semiconductor memory 1 according to the first embodiment. As illustrated in FIG. 10, in the read operation, the voltage VBL is applied to the contact plug CP1 (the drain of the transistor T9), the voltage VSS is applied to the contact plug CP3 (the drain of the transistor T10), the voltage VBLH is applied to the contact plug CP4 (the gate electrode GEa of the transistor T9), and the voltage VSS is applied to the contact plug CP5 (the gate electrode GEb of the transistor T10).

The voltage VBL is a voltage that can be generated by the sense amplifier section SA, and is, for example, 2.3 V. The voltage VSS corresponds to the ground voltage, and is, for example, 0 V. The voltage VBLH is higher than the voltage VBL, and is, for example, 8 V. The transistor T9 in which the voltages VBLH and VBL are applied to the gate electrode GEa and the drain is turned on (ON). The transistor T10 in which the voltage VSS is applied to each of the gate electrode GEb and the drain is turned off (OFF).

The transistor T9 in the ON state transfers the voltage VBL applied to the drain to the source. Then, the voltage of the bit line BL increases based on the voltage VBL applied via the silicide part 51 and the contact plug CP2. In a case where the voltage of the bit line BL increases, the channel potential of the NAND string NS rises. Thereafter, in the NAND string NS, a read voltage is applied to the memory cell transistor MT to be read, and a read pass voltage is applied to the other memory cell transistors MT. The read voltage is a voltage used for determining a threshold voltage according to data. The read path voltage is a high voltage that is turned on regardless of the data stored in the memory cell transistor MT. Then, the channel potential of the NAND string NS changes based on whether or not the memory cell transistor MT to be read is turned on. As a result, the sense amplifier section SA can determine the data stored in the selected memory cell transistor MT by detecting a change in the voltage of the bit line BL using the node SEN.

### <1-3> Effects of First Embodiment

According to the semiconductor memory 1 according to the first embodiment described above, the contact resistance with respect to the transistors T9 and T10 can be reduced, and the breakdown voltage between the transistors T9 and T10 can be improved. Hereinafter, effects of the first embodiment will be described in detail.

In a case where the circuit layout such as the latch circuit SDL is reduced in size, the diameter of the contact plug CP used in the bit line hookup portion BLHU is also reduced in size. In a case where the diameter of the contact plug CP is reduced, there are concerns about an increase in contact resistance between the contact plug CP and the coupling destination (the impurity diffusion region NP or the gate electrode GE) and variations in contact resistance.

Therefore, in the semiconductor memory 1 according to the first embodiment, silicide parts 50, 51, 52, 63, and 73 are formed in the impurity diffusion regions NP1, NP0-1, and NP0-2 and the conductive layers 62 and 72, respectively. Then, the contact plugs CP1 to CP5 are coupled to the silicide parts 50, 51, 52, 63, and 73, respectively. As a result, the semiconductor memory 1 according to the first embodiment can reduce the contact resistance of the contact plug CP used in the bit line hookup portion BLHU.

In addition, in the semiconductor memory 1, a high potential difference is generated between the transistors T9 and T10 in the erase operation. Specifically, the voltage VERA applied to the impurity diffusion region NM2 via the transistor T10 in a case where the transistors T9 and T10 are operated in the OFF state and the ON state, respectively, in the erase operation is higher than the voltage VBL applied to the impurity diffusion region NM2 via the transistor T9 in a case where the transistors T9 and T10 are operated in the ON state and the OFF state, respectively, in the read operation. Therefore, in a configuration in which one end (for example, a source) is shared between the transistors T9 and T10, a challenge arises in securing the breakdown voltage between the transistors T9 and T10. For example, in a case where the silicide part 51 reaches the impurity diffusion region NM2, the breakdown voltage between the transistors T9 and T10 may be insufficient. Therefore, it is preferable that the entire impurity diffusion region is not silicided between the transistors T9 and T10.

On the other hand, the semiconductor memory 1 according to the first embodiment has a structure in which the coupling destination of the contact plug CP used in the bit line hookup portion BLHU is silicided, and a part (VERA cutoff region) between the transistors T9 and T10 is selectively left unsilicided. The silicide part 51 is included inside the impurity diffusion region NP0-1. As a result, the semiconductor memory 1 according to the first embodiment can secure a breakdown voltage between the transistors T9 and T10 that can generate a high potential difference.

### <2> Second Embodiment

In a semiconductor memory 1a according to a second embodiment, the impurity diffusion region NP0 and the silicide region SR0 described in the first embodiment are formed by self-alignment. Hereinafter, details of the semiconductor memory 1a according to the second embodiment will be mainly described on differences from the first embodiment.

### <2-1> Configuration

First, a structure of the semiconductor memory 1a according to the second embodiment will be described.

### 1: Planar Layout of Bit Line Hookup Portion BLHU

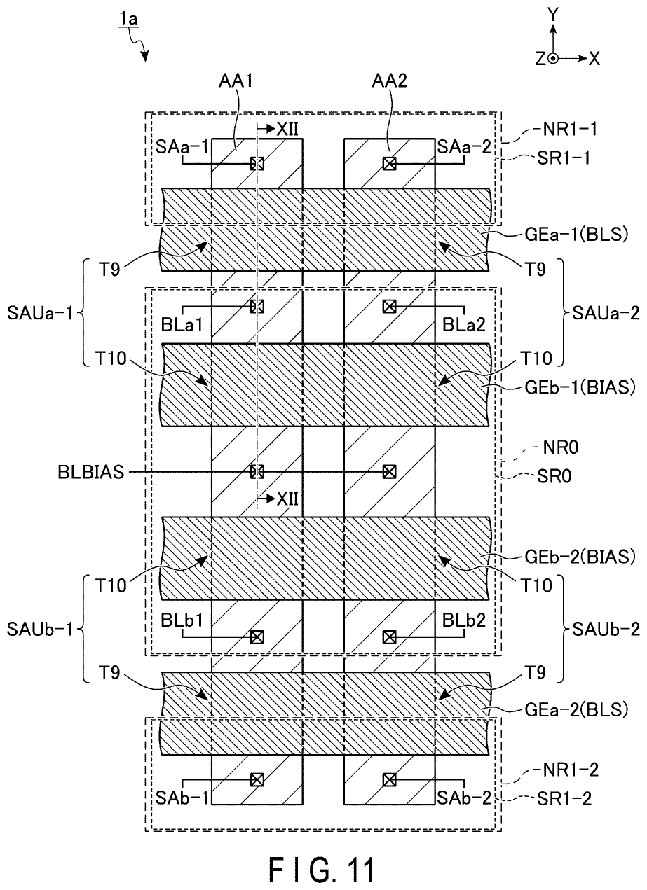

FIG. 11 is a plan view showing an example of a planar layout of a bit line hookup portion BLHU included in a sense amplifier unit SAU provided in the semiconductor memory 1a according to the second embodiment. As shown in FIG. 11, in the semiconductor memory 1a according to the second embodiment, the width of a diffusion region NR0 in the Y direction is narrower than that in the first embodiment. In the semiconductor memory 1a, the width of the diffusion region NR0 in the Y direction is substantially equal to the width of a silicide region SR0 in the Y direction.

### 2: Cross-Sectional Structure of Bit Line Hookup Portion BLHU

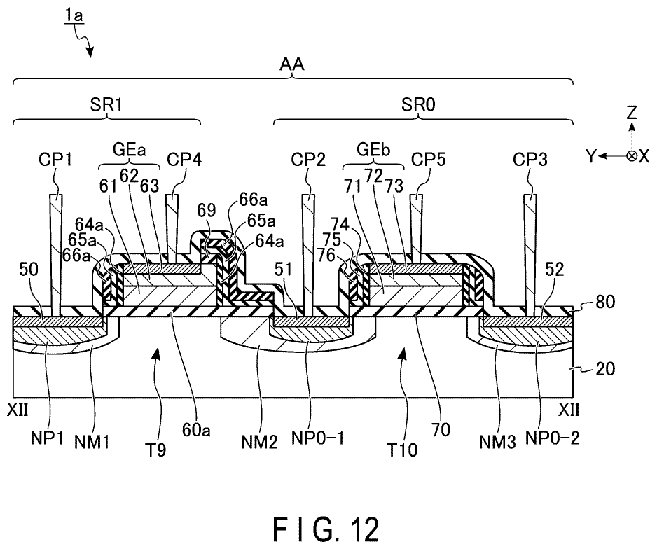

FIG. 12 is a cross-sectional view taken along line XII-XII of FIG. 11, showing an example of a cross-sectional structure of the bit line hookup portion BLHU included in the sense amplifier unit SAU provided in the semiconductor memory 1a according to the second embodiment. As shown in FIG. 12, the semiconductor memory 1a according to the second embodiment has a configuration in which insulating films 67 and 58 are omitted and an insulating layer 69 is added as compared with the semiconductor memory 1 according to the first embodiment. In addition, a gate insulating film 60 and insulating films 64, 65, and 66 in the second embodiment are shown as a gate insulating film 60a and insulating films 64a, 65a, and 66a, respectively. The insulating layer 69 is provided on a conductive layer 62. In the conductive layer 62, silicidation is suppressed in a portion covered with the insulating layer 69. Therefore, in plan view, an end of a silicide part 63 in the X direction and an end of the insulating layer 69 in the X direction are substantially aligned.

Structures of the gate insulating film 60a and the insulating films 64a, 65a, and 66a on one side in the Y direction (silicide part 50 side in plan view) are similar to those of the gate insulating film 60 and the insulating films 64, 65, and 66 of the first embodiment, respectively. In the semiconductor memory 1a, a position of an end of the insulating film 60a on the other side in the Y direction (transistor T10 side) is substantially aligned with a position of an end of a silicide part 51 on one side in the X direction (transistor T9 side). The insulating film 64a is provided on the side surfaces of the conductive layers 61 and 62 and the insulating layer 69 on the transistor T10 side. The insulating films 65a and 66a are continuously provided along the upper surface of the insulating layer 69, the upper surface and the side surface of the insulating film 64a, and the upper surface of the gate insulating film 60a. The insulating films 64a and 65a are formed in this order. In plan view, the positions of the ends of the gate insulating film 60a and the insulating films 64a and 65a on the transistor T10 side are substantially aligned. The gate insulating films 60a and 70 are collectively formed. The insulating films 64a, 65a, and 66a are collectively formed with insulating films 74,75, and 76, respectively. In the semiconductor memory 1a, the insulating films 65a and 75 may be omitted. In the semiconductor memory 1a, a set of the gate insulating film 60a, the conductive layers 61 and 62, the silicide part 63, and the insulating films 64a, 65a, and 66a is a structure associated with the transistor T9. Similarly to the first embodiment, an insulating film 80 of the second embodiment is provided so as to cover the structure associated with the transistor T9, the structure associated with the transistor T10, and the upper surface of a substrate 20.

Furthermore, in the semiconductor memory 1a according to the second embodiment, impurity diffusion regions NP1, NP0-1 and NP0-2 and silicide parts 50, 51 and 52 are formed by self-alignment. Specifically, first, the impurity diffusion regions NP1, NP0-1, and NP0-2 are formed in the opening of the mask by the ion implantation process using the structure (gate insulating film 60a, conductive layers 61 and 62, silicide part 63, insulating films 64a, 65a and 66a, and insulating layer 69) corresponding to the transistor T9 and the structure (gate insulating film 70, conductive layers 71 and 72, silicide part 73, and insulating films 74 to 76) corresponding to the transistor T10 as masks. Thereafter, by performing silicidation, the silicide parts 50, 51, and 52 are formed in portions of the impurity diffusion regions NP1, NP0-1, and NP0-2, the upper portions of which are not covered with the gate insulating films 60a and 70 (oxide films), respectively, and the silicide parts 63 and 73 are formed in portions of the conductive layers 62 and 72, the upper portions of which are not covered with the insulating layer 69, respectively.

Therefore, in the semiconductor memory 1a, the positions of one end and the other end in the X direction of the impurity diffusion region NP0-1 are close to the positions of one end and the other end in the X direction of the silicide part 51, respectively. Similarly, the positions of one end and the other end in the X direction of the impurity diffusion region NP0-2 are close to the positions of one end and the other end in the X direction of the silicide part 52, respectively. Positions of one end and the other end in the X direction of the impurity diffusion region NP1 are close to positions of one end and the other end in the X direction of the silicide part 50, respectively. The impurity diffusion regions NP1, NP0-1, and NP0-2 may have a portion wider than the end of the mask by the heat treatment after the ion implantation process. Therefore, even in a case where the silicide parts are formed by self-alignment, the silicide parts 50 is separated from a boundary portion of the impurity diffusion regions NM1 and NP1. Similarly, the silicide part 51 is separated from a boundary portion between the impurity diffusion regions NM2 and NP0-1. The silicide part 52 is separated from a boundary portion between the impurity diffusion regions NM3 and NP0-2. Other configurations of the semiconductor memory 1a according to the second embodiment are similar to those of the first embodiment.

### <2-2> Effects of Second Embodiment

Similarly to the first embodiment, according to the semiconductor memory 1a according to the second embodiment, the contact resistance with respect to the transistors T9 and T10 can be reduced, and the breakdown voltage between the transistors T9 and T10 can be improved. Furthermore, in the semiconductor memory 1a according to the second embodiment, by providing the insulating layer 69, a region where the conductive layer 62 is silicided is more distinctly formed than in the first embodiment. Furthermore, in the semiconductor memory 1a according to the second embodiment, since the impurity diffusion region NP0-1 and the silicide part 51 are formed by self-alignment using the gate insulating films 60a and 70, the circuit area can be reduced as compared with the first embodiment. Therefore, the semiconductor memory 1a according to the second embodiment can suppress the manufacturing cost of the semiconductor memory 1a.

### <3> Others

The effects (advantages) described in the semiconductor memories 1 and 1a described in the above embodiments can also be realized in a semiconductor device including two transistors that are coupled to each other like the transistors T9 and T10 and can be used with a high potential difference. That is, the circuit configuration and structure such as the bit line hookup portion BLHU described in the above embodiments can also be applied to a semiconductor device other than the semiconductor memory. Depending on the circuit configuration of the semiconductor device, the relationship between the sources and the drains of the transistors T9 and T10 described in the above embodiments may be interchanged. That is, in the semiconductor device according to the above embodiments, two transistors corresponding to the transistors T9 and T10 may share either the source or the drain.

In the above embodiments, the circuit configuration, planar layout, and cross-sectional structure of the semiconductor memory 1 can be changed as appropriate. For example, in the above embodiments, the case where the semiconductor film 41 of the memory pillar MP and the source line SL (semiconductor layer 22) are coupled via the side surface of the memory pillar MP has been exemplified, but the present invention is not limited thereto. The semiconductor film 41 of the memory pillar MP and the source line SL (semiconductor layer 22) may be electrically coupled via the bottom of the memory pillar MP. The semiconductor memory 1 may have a structure in which a chip on which the memory cell array 10 is provided and a chip on which a circuit or the like other than the memory cell array 10 is provided are bonded together.

In the above embodiment, the concentration of the n-type impurity in each of the impurity diffusion regions NM1 to NM3 is, for example, 5×10¹⁷ cm⁻³, and is preferably set within a range of 5×10¹⁶ cm⁻³ to 5×10¹⁸ cm⁻³. The concentration of the n-type impurity in each of the impurity diffusion regions NP1, NP0-1, and NP0-2 is, for example, 1×10²¹ cm⁻³, and preferably set within a range of 1×10²⁰ cm⁻³ to 5×10²¹ cm⁻³. For example, the boundary between the impurity diffusion amount region NP0-1 and the impurity diffusion region NM2 is indicated by a portion where the concentration of the n-type impurity is lower than 1×10¹⁸ cm⁻³.

In the present specification, the term “coupling” means that elements are electrically coupled, and does not exclude the case where another element is interposed in between. “Electrically coupled” may be via an insulator as long as it can operate in the same manner as electrically coupled. The “cylindrical shape” indicates a structure provided in a hole formed in the manufacturing process of the semiconductor memory 1. The voltage applied to the stacked wiring may be estimated based on the voltage of the signal line coupling the driver circuit 15 and the row decoder module 16. The “region” may be regarded as a configuration included by the reference substrate 20. The “metal silicide” may be referred to as “silicide”. The “impurity diffusion region” may be referred to as “diffusion region”. The “plan view” means, for example, visually recognizing the component from above. The “visually recognizing” includes observing an object using a microscope, a camera, or the like. The “conductivity type” corresponds to either an n-type or a p-type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising a first transistor and a second transistor that share one end, the semiconductor device comprising:
a substrate including a first impurity diffusion region and a second impurity diffusion region, the first impurity diffusion region corresponding to the one end of the first transistor and the second transistor, the second impurity diffusion region having a higher impurity concentration than the first impurity diffusion region in the first impurity diffusion region, wherein a first silicide part is formed on the second impurity diffusion region;
a first insulating film and a second insulating film provided in a first direction on the substrate, the first insulating film corresponding to a gate insulating film of the first transistor, and the second insulating film corresponding to a gate insulating film of the second transistor;
a first conductive layer provided on the first insulating film and corresponding to a gate electrode of the first transistor, wherein a second silicide portion is formed on the first conductive layer except a part of the first conductive layer;
a second conductive layer provided on the second insulating film and corresponding to a gate electrode of the second transistor, wherein a third silicide portion is formed on the second conductive layer; and
a first contact plug, a second contact plug, and a third contact plug respectively coupled to the first silicide part, the second silicide part, and the third silicide part, wherein
in plan view, the part of the first conductive layer is disposed between the first silicide part and the second silicide part.

2. The semiconductor device according to claim 1, wherein
the substrate has a portion containing no silicide on the first insulating film side between the first insulating film and the second insulating film in plan view.

3. The semiconductor device according to claim 2, wherein
in plan view, an interval between the first silicide part and the second silicide part in the first direction is wider than an interval between the first silicide part and the third silicide part in the first direction.

4. The semiconductor device according to claim 1, wherein
the first impurity diffusion region includes a portion facing each of the first insulating film and the second insulating film in a second direction intersecting a surface of the substrate, and
in plan view, an interval between the first conductive layer and the second impurity diffusion region in the first direction is wider than an interval between the second conductive layer and the second impurity diffusion region in the first direction.

5. The semiconductor device according to claim 1, wherein
the first silicide part is separated from a boundary portion between the first impurity diffusion region and the second impurity diffusion region.

6. The semiconductor device according to claim 1, further comprising:
a third insulating film provided on a side surface of the first conductive layer; and
a fourth insulating film continuously provided along an upper surface of the part of the first conductive layer, the third insulating film, and an upper surface excluding the first silicide part in the first impurity diffusion region.

7. The semiconductor device according to claim 6, wherein
the fourth insulating film contains oxygen and silicon.

8. The semiconductor device according to claim 1, wherein
a position of an end of the second impurity diffusion region on one side in the first direction substantially coincides with a position of an end of the first silicide part on one side in the first direction in plan view, and
in plan view, a position of an end of the second impurity diffusion region on the other side in the first direction substantially coincides with a position of an end of the first silicide part on the other side in the first direction.

9. The semiconductor device according to claim 1, wherein
each of the first conductive layer and the second conductive layer contains polysilicon.

10. The semiconductor device according to claim 1, wherein
each of the first silicide part, the second silicide part, and the third silicide part contains at least one of nickel and platinum.

11. The semiconductor device according to claim 1, wherein
the substrate is a silicon substrate of a first conductivity type, and
an impurity concentration of a second conductivity type different from the first conductivity type in the first impurity diffusion region is in a range of 5×10¹⁷ cm⁻³ to 5×10¹⁸ cm⁻³, and
an impurity concentration of the second conductivity type in the second impurity diffusion region is in a range of 1×10²⁰ cm⁻³ to 5×10²¹ cm⁻³.

12. The semiconductor device according to claim 1, wherein
a voltage applied to the first impurity diffusion region via the second transistor in a case where the first transistor and the second transistor are operated in an OFF state and an ON state, respectively, is higher than a voltage applied to the first impurity diffusion region via the first transistor in a case where the first transistor and the second transistor are operated in an ON state and an OFF state, respectively.

13. A semiconductor memory, comprising:
a semiconductor device according to claim 1;
a plurality of third conductive layers arranged apart from each other in a second direction intersecting a surface of the substrate; and
a semiconductor film provided extending in the second direction, wherein a portion where the semiconductor film and the third conductive layer intersect each other functions as a memory cell, and one end of the semiconductor film is electrically coupled to the one end of the first transistor.

14. The semiconductor memory according to claim 13, further comprising:
a bit line coupled between the semiconductor film and the one end of the first transistor; and
a sense amplifier coupled to the other end of the first transistor.

15. The semiconductor memory according to claim 13, further comprising:
a sequencer configured to:
in a read operation, operate the first transistor and the second transistor in an ON state and an OFF state, respectively, and apply a first voltage to the first impurity diffusion region via the first transistor; and
in an erase operation, operate the first transistor and the second transistor in an OFF state and an ON state, respectively, and apply a second voltage higher than the first voltage to the first impurity diffusion region via the second transistor.
